(19) United States
(12) Patent Application Publication
(10) Pub. No.: US 2025/0201579 A1
(43) Pub. Date: Jun. 19, 2025

(54) PLANARIZATION APPARATUS AND ARTICLE MANUFACTURING METHOD

(71) Applicant: CANON KABUSHIKI KAISHA, Tokyo (JP)

(72) Inventors: SHINTARO SUZUKI, Tochigi (JP); KEN KATSUTA, Saitama (JP)

(21) Appl. No.: 18/968,235

(22) Filed: Dec. 4, 2024

(30) Foreign Application Priority Data
Dec. 15, 2023 (JP) 2023-212322

(51) Int. Cl. H01L 21/321; B05D 3/06; G03F 7/00

(52) U.S. Cl. CPC H01L 21/32115; B05D 3/067; G03F 7/0002

(57) ABSTRACT

The present invention provides a planarization apparatus that planarizes a composition on a substrate by using a member having a flat surface, the apparatus comprising: a first processing device configured to perform curing processing of curing the composition on the substrate in a contact state in which the flat surface of the member is in contact with the composition; a second processing device configured to perform separation processing of separating the member from the composition on the substrate that has undergone the curing processing by the first processing device and is in the contact state; and a conveyance mechanism configured to convey the substrate having undergone the curing processing by the first processing device to the second processing device, wherein the second processing device includes an ion generator configured to ionize a gas around the substrate in the contact state.

### BACKGROUND OF THE INVENTION

### Field of the Invention

The present invention relates to a planarization apparatus and an article manufacturing method.

### Description of the Related Art

With a growing demand for the miniaturization of semiconductor devices and the like, much attention has been paid to imprint techniques that can form, on a substrate, a film (structure) controlled on the order of several nanometers in addition to conventional photolithography techniques. An imprint technique is a microfabrication technique of forming a composition on a substrate by using a mold (member). For example, an imprint technique using a photo-curing method cures an uncured composition supplied onto a substrate by irradiating the composition with light while the composition is in contact with a mold and separates the cured composition from the mold, thereby molding the composition on the substrate.

In a manufacturing process for a semiconductor device or the like, there is a need to form a planarized film (that is, a film having a flat surface) on a substrate on which various patterns are formed. As a general planarization technique of forming a planarized film on a substrate in this manner, a technique of forming a coating film on a substrate by using a coating apparatus such as a spin coater is known. However, in the method of forming a coating film on a substrate by using a coating apparatus, it is difficult to control unevenness on a substrate on the nanoscale order. Accordingly, there has recently been proposed a planarization technique of planarizing a composition on a substrate by using a mold (member) having a flat surface, with an imprint technique being applied. The planarization technique using the imprint technique is configured to cure a composition supplied onto a substrate while the composition is in contact with the flat surface of a mold and separate the cured composition from the mold, thereby planarizing the composition on the substrate. A mold used for such a planarization technique is sometimes called a plane template or superstrate.

The planarization technique sometimes exhibits a phenomenon, so-called peeling charge, in which a mold is charged when the mold is peeled from a cured composition on a substrate. When such peeling charge occurs, surrounding foreign substances (particles) are sometimes attracted and attached to the mold. If the mold to which foreign substances are attached is brought into contact with the composition on the substrate, a defect may occur in the planarized film formed on the substrate or the mold may break.

Japanese Patent Laid-Open No. 2017-55110 proposes a technique of neutralizing a mold having a concave-convex pattern by causing soft X-rays to pass through the gap formed between the mold and a substrate after the mold is separated from a composition on the substrate. However, in general, in the planarization technique, since a mold comes into contact with a composition on the entire region of a substrate, it is difficult to cause soft X-rays to pass through the gap between the mold and the substrate as in the method disclosed in Japanese Patent Laid-Open No. 2017-55110.

### SUMMARY OF THE INVENTION

The present invention provides a technique advantageous in neutralizing a member suffering peeling charge in a planarization technique.

According to one aspect of the present invention, there is provided a planarization apparatus that planarizes a composition on a substrate by using a member having a flat surface, the apparatus comprising: a first processing device configured to perform curing processing of curing the composition on the substrate in a contact state in which the flat surface of the member is in contact with the composition; a second processing device configured to perform separation processing of separating the member from the composition on the substrate that has undergone the curing processing by the first processing device and is in the contact state; and a conveyance mechanism configured to convey the substrate having undergone the curing processing by the first processing device to the second processing device, wherein the second processing device includes an ion generator configured to ionize a gas around the substrate in the contact state.

Further features of the present invention will become apparent from the following description of exemplary embodiments with reference to the attached drawings.

### BRIEF DESCRIPTION OF THE DRAWINGS

FIG. 1 is a schematic view showing an arrangement example of a planarization apparatus according to an embodiment of the present invention;

FIG. 2 is a sequence chart showing a procedure of planarization processing;

FIGS. 3A to 3C are schematic views for explaining contact processing;

FIG. 4 is a schematic view for explaining curing processing;

FIGS. 5A to 5C are schematic views for explaining separation processing;

FIGS. 6A and 6B are schematic views for explaining the movement of a substrate having undergone separation processing to an unload position;

FIGS. 7A and 7B are views for explaining a placement example of an ion generator;

FIGS. 8A and 8B are views for explaining a placement example of the ion generator;

FIGS. 9A and 9B are views showing an arrangement example of a second processing device having a potential measuring device;

FIG. 10A is a view showing an arrangement example of a planarization apparatus having a third processing device;

FIG. 10B is a view showing an arrangement example of the planarization apparatus having a hand as a conveyance device; and

FIGS. 11A to 11D are views for explaining planarization processing.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate (that is, the holding surface that holds the substrate) are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that is specified based on coordinates on the X-, Y-, and Z-axes, and an orientation is information that is specified by values on the θX-, θY-, and θZ-axes. Positioning means controlling the position and/or orientation.

A planarization apparatus according to an embodiment of the present invention will be described. The planarization apparatus is a lithography apparatus that planarizes (molds) a composition on a substrate by using a member (mold) having a flat surface and can be used for a lithography process as a manufacturing process for a semiconductor device, magnetic storage medium, or the like. The member (mold) having the flat surface is sometimes called a plane template or superstrate, which will be sometimes written as a “plane template” hereinafter.

As a composition supplied onto a substrate, a curable composition (to be sometimes called an uncured resin) is used, which is cured when energy for curing is applied to it. As energy for curing, an electromagnetic wave, heat, or the like is used. An electromagnetic wave includes, for example, light selected from the wavelength range of 10 nm or more and 1 mm or less, specifically, infrared light, visible light, ultraviolet light, and the like. A curable composition is a composition that is cured by being irradiated with light or by heating. Of such curable compositions, the curable composition that is cured by being irradiated with light contains at least a polymerizable compound and a photopolymerization initiator and may contain a non-polymerizable compound or a solvent as needed. The non-polymerizable compound is at least one type of compound selected from the group consisting of a sensitizer, a hydrogen donor, an internal mold release agent, a surfactant, an antioxidant, a polymer component, and the like. A composition is provided in a film form on a substrate by a spin coater or slit coater. Alternatively, a composition may be provided, on a substrate, in a droplet form or in an island or film form with a plurality of droplets connected to each other by a liquid spray head. An imprint material has a viscosity (at 25° C.) of, for example, 1 mPa·s or more or 100 mPa·s or the less.

When a photo-curable composition is to be used, a plane template (mold) is preferably formed from a light transmissive material. Specific examples of the material for a plane template are preferably glass, quartz, polymethyl methacrylate (PMMA), a soft film such as a polycarbonate resin, a photo-cured film, and a metal film. The plane template can be a circle having a diameter of 300 mm or more or 500 mm or less, but limitation is not made thereto. The plane template can have a thickness of 0.25 mm or more or 2 mm or less, but limitation is not made thereto. Examples of the material for a substrate are glass, ceramics, metals, semiconductors, and resins. A member made of a material different from that of the substrate may be provided on the obverse surface of the substrate. The substrate includes, for example, a silicon wafer, a compound semiconductor wafer, and silica glass. The substrate has a concave-convex structure originating from the pattern formed in a previous process. The planarization apparatus can be used to form a planarized film covering the concave-convex structure on a substrate.

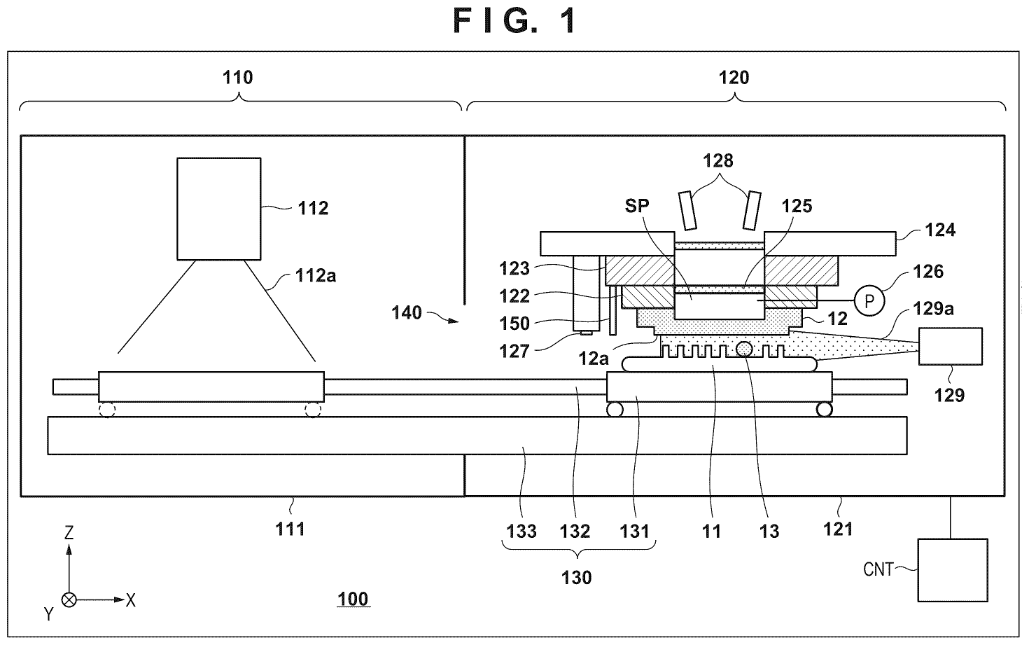

FIG. 1 is a schematic view showing an arrangement example of a planarization apparatus 100 according to this embodiment. The planarization apparatus 100 cures an uncured composition 13 supplied onto a substrate 11 while the composition 13 is in contact with a flat surface 12a of a plane template 12 and then separates the plane template 12 from the cured composition 13. This makes it possible to form a planarized film (that is, a film having a flat surface) formed of the cured composition 13 on the substrate 11. This processing is called planarization processing. When the plane template 12 having dimensions (size) that cover the entire region of the substrate 11 is to be used, a planarized film formed of the cured composition 13 is collectively formed on the entire region of the substrate 11. Note that this embodiment will exemplify the use of a photo-curing method of curing the composition 13 by irradiating the composition 13 on the substrate 11 with light (ultraviolet light).

The planarization apparatus 100 can include a plurality of processing devices, each performing predetermined processing for the substrate 11, a conveyance mechanism 130 that conveys the substrate 11 between a plurality of processing devices, and a controller CNT. As shown in FIG. 1, the planarization apparatus 100 according to this embodiment is provided with a first processing device 110 and a second processing device 120 as a plurality of processing devices.

The first processing device 110 is a module that performs curing processing of curing the composition 13 in a state in which the flat surface 12a of the plane template 12 is in contact with the composition 13 on the substrate 11 (this state will sometimes be referred to as the contact state hereinafter). The first processing device 110 includes a curing device 112 (UV light source) that cures the composition 13 on the substrate in the contact state by irradiating the composition 13 on the substrate 11 with light 112a (ultraviolet light).

The second processing device 120 is a module that performs separation processing of separating the plane template 12 from the composition 13 on the substrate 11 with respect to the substrate 11 that has undergone the curing processing by the first processing device 110 and is in the contact state. In addition, the second processing device 120 according to this embodiment can be configured to perform contact processing of bringing the plane template 12 into contact with the composition 13 on the substrate 11 before the first processing device 110 performs curing processing. An arrangement example of the second processing device 120 will be described later.

The first processing device 110 and the second processing device 120 are arranged side by side. The internal space of a chamber 111 of the first processing device 110 communicates with the internal space of a chamber 121 of the second processing device 120 through an unload inlet 140. The installation position of the unload inlet 140 may be also understood as a position also serving as an unload position at which the substrate 11 having undergone planarization processing is unloaded from the planarization apparatus 100.

The conveyance mechanism 130 is a mechanism of conveying the substrate 11 between the first processing device 110 and the second processing device 120. The conveyance mechanism 130 according to this embodiment can include a stage 131 (substrate holder) that can move the substrate 11 over the first processing device 110 and the second processing device 120 while holding the substrate 11 and a substrate driver 132 that drives the substrate 11 by driving the stage 131. The stage 131 is shared by the first processing device 110 and the second processing device 120 and configured to move on a base 133 provided over the first processing device 110 and the second processing device 120 through the unload inlet 140. The substrate driver 132 includes an actuator such as a linear motor and drives the stage 131 (the substrate 11) over the first processing device 110 and the second processing device 120. The conveyance mechanism 130 can convey the substrate 11 between the first processing device 110 and the second processing device 120 by moving the stage 131 holding the substrate 11 on the base 133 over the first processing device 110 and the second processing device 120.

The controller CNT is formed of a computer (information processor) including a processor such as a central processing unit (CPU) and a storage device such as a memory. The controller CNT is connected to each device of the planarization apparatus 100 via lines and controls each device of the planarization apparatus 100. That is, the controller CNT controls planarization processing by controlling a plurality of processing devices (the first processing device 110 and the second processing device 120) and the conveyance mechanism 130. In addition, the controller CNT may be formed of a programmable logic device (PLD) such as a field programmable gate array (FPGA) or an application specific integrated circuit (ASIC).

An arrangement example of the second processing device 120 will be described next with reference to FIG. 1. The second processing device 120 can include a mold holder 122 that holds the plane template 12 (mold), a mold driver 123 that drives the plane template 12 by driving the mold holder 122 in the Z direction, and a support member 124 that supports the mold driver 123. The second processing device 120 performs contact processing and separation processing in a state in which the substrate 11 held by the stage 131 of the conveyance mechanism 130 is placed at a processing position. The processing position is a position at which the substrate 11 should be placed below the mold holder 122 to perform contact processing and separation processing.

The substrate driver 132 of the conveyance mechanism 130 and the mold driver 123 of the second processing device 120 constitute a relative driving mechanism that relatively drives the substrate 11 and the plane template 12 so as to adjust the relative positions of the substrate 11 and the plane template 12 at the second processing device 120. The adjustment of the relative positions of the substrate 11 and the plane template 12 by the relative driving mechanism includes driving for bringing the composition 13 on the substrate 11 into contact with the plane template 12 and driving for separating the plane template 12 from the cured composition 13 on the substrate 11. The adjustment of the relative positions of the substrate 11 and the plane template 12 by the relative driving mechanism also includes alignment between the substrate 11 and the plane template 12. The substrate driver 132 is configured to drive the substrate 11 along a plurality of axes (for example, three axes, namely the X-axis, the Y-axis, and the θZ-axis, preferably, six axes, namely the X-axis, the Y-axis, the Z-axis, the θX-axis, the θY-axis, and the θZ-axis). The mold driver 123 is configured to drive the plane template 12 along a plurality of axes (for example, three axes, namely the Z-axis, the θX-axis, and the θY-axis, preferably, six axes, namely the X-axis, the Y-axis, the Z-axis, the θX-axis, the θY-axis, and the θZ-axis).

The mold holder 122 and the mold driver 123 include a space defining member 125 for defining (forming) a pressure control space SP on the back surface side of the plane template 12 (the surface on the opposite side to the flat surface facing the substrate 11). The pressure control space SP is substantially sealed by the plane template 12 and the space defining member 125 while the plane template 12 is held by the mold holder 122. A pressure controller 126 adjusts the internal pressure of the pressure control space SP. For example, the pressure controller 126 can deform the plane template 12 into a convex shape with its central portion protruding toward the substrate 11 by increasing the internal pressure of the pressure control space SP to a pressure higher than the atmospheric pressure. Deforming the plane template 12 into a convex shape in contact processing makes it possible to gradually bring the plane template 12 into contact with the composition 13 on the substrate 11 starting from the central portion, thus reducing the confinement of air bubbles between the plane template 12 and the substrate 11. In addition, deforming the plane template 12 into a convex shape in separation processing makes it possible to facilitate separating the plane template 12 from the cured composition 13 on the substrate 11.

The second processing device 120 can further include a supply device 127 and a measuring device 128. The supply device 127 (dispenser) supplies (places and distributes) the composition 13 in the form of a plurality of liquid droplets onto the substrate 11. If, however, the substrate 11 onto which the composition 13 is supplied by an external apparatus of the planarization apparatus 100 is loaded into the planarization apparatus 100, the second processing device 120 need not be provided with the supply device 127. Alternatively, if the planarization apparatus 100 is provided with a processing device for supplying the composition 13 onto the substrate 11 separately from the second processing device 120, the second processing device 120 need not be provided with the supply device 127. In addition, the measuring device 128 measures the positional shift (alignment error) between the substrate 11 and the plane template 12. More specifically, the measuring device 128 detects the relative positions of a mark on the substrate 11 and a mark on the plane template 12 via the space defining member 125 and measures the positional shift between the substrate 11 and the plane template 12 based on the detection result. In this case, the space defining member 125 is preferably formed of a member that transmits light so that the measuring device 128 can detect the marks on the substrate 11 and the plane template 12.

In separation processing performed by the second processing device 120, a phenomenon, so-called peeling charge, can occur in which the plane template 12 is charged when the plane template 12 is separated from the cured composition 13 on the substrate 11. When such peeling charge occurs, surrounding foreign substances (particles) are sometimes attracted and attached to the plane template 12. If the plane template 12 is brought into contact with the composition 13 on the substrate 11 while foreign substances are attached to the plane template 12, a defect may occur in the planarized film formed on the substrate 11 or the plane template 12 may break.

Accordingly, in the planarization apparatus 100 according to this embodiment, the second processing device 120 is provided with an ion generator 129. The ion generator 129 is also called an ionizer and configured to ionize a gas around the substrate 11 in a contact state in which the flat surface 12a of the plane template 12 is in contact with the composition 13 on the substrate 11. This makes it possible to reduce peeling charge that can occur on the plane template 12 in separation processing. The ion generator 129 (ionizer) includes several types of ion generators such as a corona discharging ion generator and an energy ray (for example, X-ray or α-ray) irradiation ion generator. In general, since a coronal discharging ion generator can be, by itself, a factor that generates particles, it is preferable to use an X-ray irradiation ion generator or α-ray irradiation ion generator that can perform neutralization while maintaining its cleanliness. When an X-ray irradiation ion generator or α-ray irradiation ion generator is to be used, the plane template 12 is neutralized by generating ions around the plane template 12 by directly irradiating the plane template 12 with X-rays or α-rays. In general, the range of α-rays is short, and α-rays are lost at several cm from an α-ray source. In contrast to this, X-rays reach several tens of centimeters to several meters from an X-ray source, although it depends on the energy. Accordingly, when it comes to neutralization in a certain degree of range using one irradiation source, the X-ray irradiation ion generator is more advantageous. However, when the plane template 12 is directly irradiated with X-rays or α-rays, the deterioration of the plane template 12 can be promoted. For this reason, the ion generator 129 according to this embodiment is configured to ionize a gas around the substrate 11 or the plane template 12 in the contact state. In this case, the ion generator 129 according to the embodiment includes an emitter that emits soft X-rays and adopts a scheme of ionizing a gas around the substrate 11 or the plane template 12 in the contact state by irradiating the gas with soft X-rays 129a emitted from the emitter.

In addition, foreign substances are also attached to the upper surface of the stage 131 of the conveyance mechanism 130 and the like. Foreign substances attached to the stage 131 vary in attachment strength. Foreign substances attached to the stage 131 are not attached to the plane template 12 unless the foreign substance are separated from the stage 131. In contrast, if the foreign substances attached to the stage 131 are separated from the stage 131, the foreign substances can be attached to the plane template 12. More specifically, an electrostatic force (coulombic force) acts on the foreign substances due to the electric field formed between the stage 131 and the plane template 12 on which peeling charge has occurred. When the electrostatic force exceeds the attachment force of the foreign substances, the foreign substances can be separated from the stage 131 and attracted and attached to the plane template 12. The upper surface of the stage 131 is sometimes configured to have the same height as that of the upper surface of the substrate 11. In this case, the distance between the plane template 12 and the upper surface of the stage 131 is small. The electrostatic force is inversely proportional to the square of the distance. Accordingly, the electrostatic force acting on foreign substances on the stage 131 can be considerably larger than the electrostatic force acting between the plane template 12 and the base 133 or its surrounding member in the absence of the stage 131 below the plane template 12. When, therefore, peeling charge has occurred on the plane template 12, many foreign substances attached on the stage 131 due to planarization processing performed many times may be separated from on the stage 131 and attached to the plane template 12.

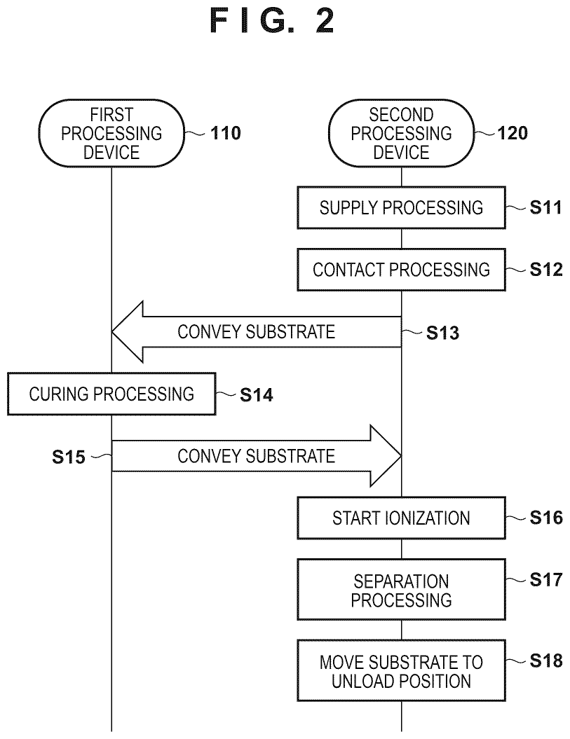

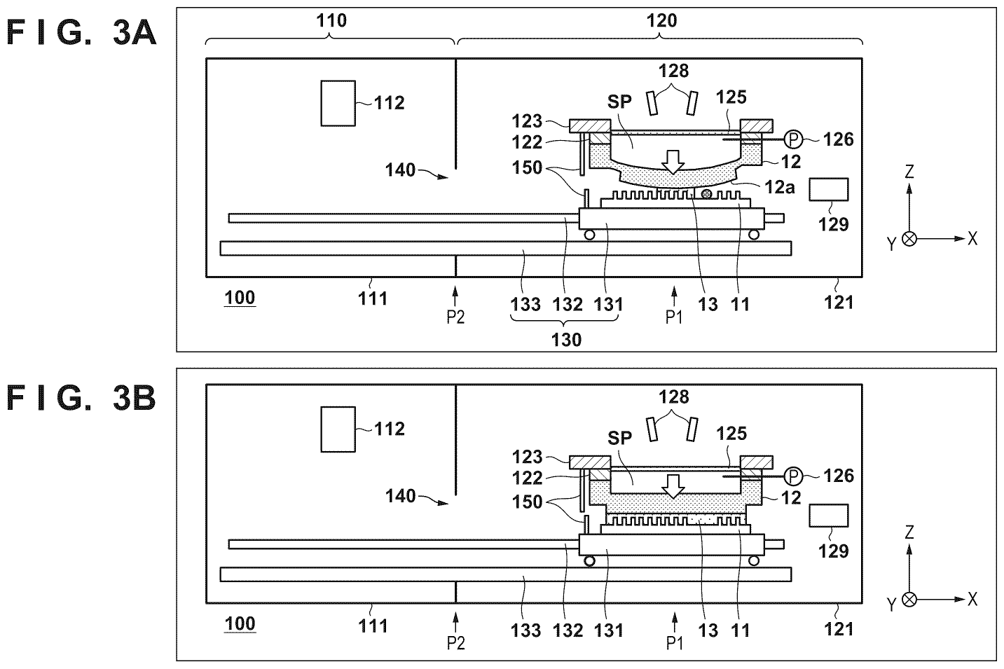

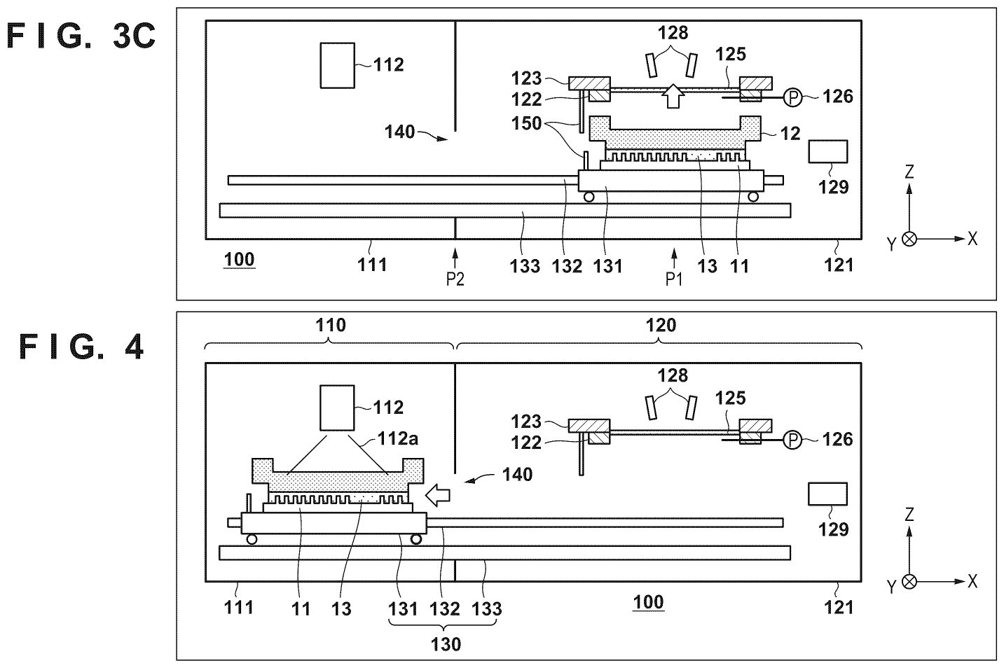

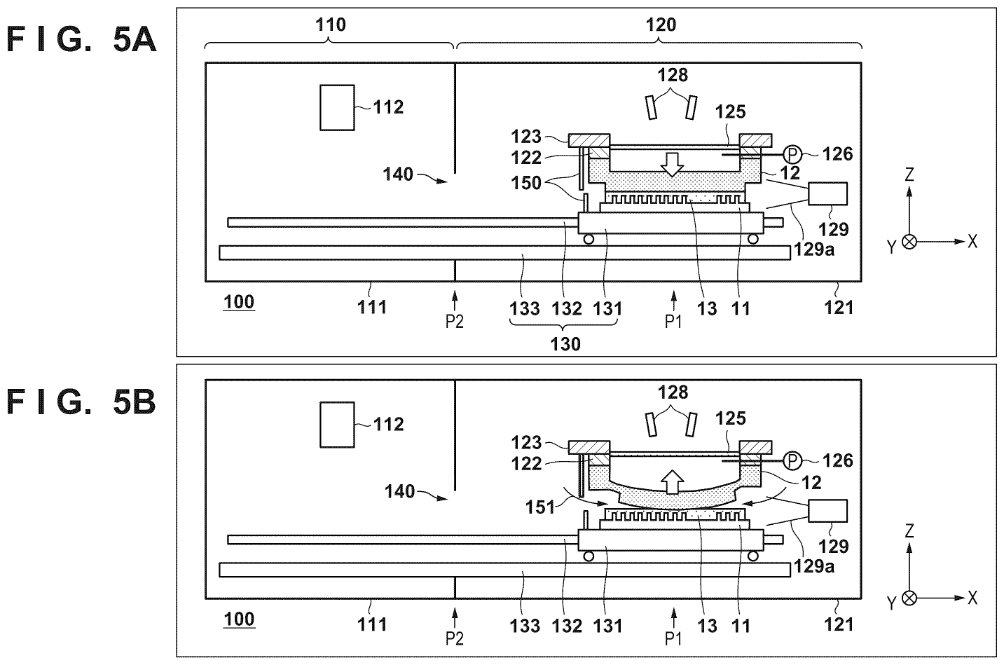

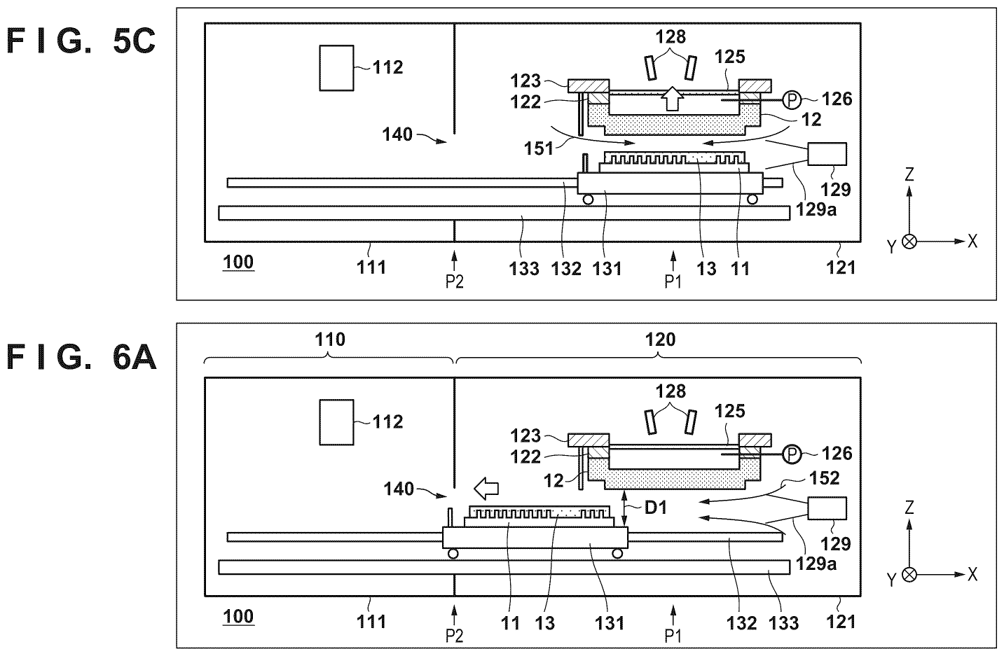

Planarization processing performed by the planarization apparatus 100 according to this embodiment will be described next. FIG. 2 is a sequence chart showing a procedure of planarization processing performed by the planarization apparatus 100 (the first processing device 110 and the second processing device 120) according to the embodiment. The planarization processing shown in the sequence chart of FIG. 2 is started while the substrate 11 is held by the stage 131 of the conveyance mechanism 130. The controller CNT controls this processing. FIGS. 3 to 6 are schematic views for explaining the respective processes included in planarization processing. FIG. 3 is a schematic view for explaining contact processing of bringing the plane template 12 into contact with the composition 13 on the substrate 11. FIG. 4 is a schematic view for explaining curing processing of curing the composition 13 on the substrate 11 with which the flat surface of the plane template 12 is in contact. FIG. 5 is a schematic view for explaining separation processing of separating the plane template 12 from the cured composition 13 on the substrate 11. FIG. 6 is a schematic view for explaining the movement of the substrate 11 having undergone separation processing to an unload position P2. FIGS. 3 to 6 show only portions necessary for explanation while an illustration of the remaining portions is omitted.

In step S11, the controller CNT causes the second processing device 120 to perform supply processing. The supply processing is the processing of supplying the composition 13 onto the substrate 11. For example, the controller CNT causes the supply device 127 to discharge the composition 13 in the form of a plurality of liquid droplets while moving the substrate 11 below the supply device 127. The substrate driver 132 drives the stage 131 to move the substrate 11 below the supply device 127. This makes it possible to supply the composition 13 in the form of a plurality of liquid droplets onto the substrate 11. After the supply processing, the process may stand by for a predetermined time to volatilize the solvent contained in the composition 13 supplied onto the substrate 11.

In step S12, the controller CNT causes the second processing device 120 to perform contact processing. The contact processing is the processing of bringing the flat surface 12a of the plane template 12 into contact with the composition 13 supplied onto the substrate 11. In the contact processing according to this embodiment, control can be performed to deform the plane template 12 into a convex shape. In addition, the contact processing is performed while the substrate 11 is placed at a processing position P1.

For example, the controller CNT deforms the plane template 12 into a convex shape by causing the pressure controller 126 to control the pressure of the pressure control space SP. At this time, the mold driver 123 positions the plane template 12 in the Z direction to prevent the plane template 12 after deformation from coming into contact with the composition 13 on the substrate 11. In addition, the controller CNT causes the measuring device 128 to measure the positional shift between the substrate 11 and the plane template 12 and positions the substrate 11 and the plane template 12 in the X and Y directions based on the measurement result. The controller CNT performs this positioning by causing the substrate driver 132 to drive the substrate 11 (the stage 131).

Subsequently, as shown in FIG. 3A, the controller CNT causes the mold driver 123 to lower the plane template 12 while controlling the pressure of the pressure control space SP (that is, the deformation amount of the plane template 12). That is, the controller CNT reduces the distance between the plane template 12 and the substrate 11. At this time, the force generated by the mold driver 123 is called a pressing force, which is controlled by the controller CNT. In addition, the controller CNT causes the pressure controller 126 to control the pressure of the pressure control space SP so as to gradually reduce the deformation amount of the plane template 12 with an increase in the contact area between the composition 13 on the substrate 11 and the plane template 12. That is, the controller CNT causes the pressure controller 126 to control the pressure of the pressure control space SP so as to make the substrate 11 parallel to the plane template 12 when the plane template 12 comes into contact with the composition 13 on the entire region of the substrate 11. This makes it possible to form the liquid film of the composition 13 having a uniform thickness as shown in FIG. 3B between the plane template 12 and the substrate 11.

Upon forming the liquid film of the composition 13 between the plane template 12 and the substrate 11, the controller CNT causes the mold holder 122 to release the plane template 12. As shown in FIG. 3C, the controller CNT then causes the mold driver 123 to raise the mold holder 122. That is, the controller CNT increases the distance between the mold holder 122 and the plane template 12 that is in contact with the composition 13 on the substrate 11.

In step S13, the controller CNT causes the conveyance mechanism 130 to convey the substrate 11 in the contact state in which the plane template 12 is in contact with the composition 13 from the second processing device 120 to the first processing device 110. For example, the controller CNT causes the substrate driver 132 of the conveyance mechanism 130 to move the stage 131 from the second processing device 120 to the first processing device 110. This makes it possible to convey the substrate 11 in the contact state, which is held by the stage 131, from the second processing device 120 to the first processing device 110.

In step S14, the controller CNT causes the first processing device 110 to perform curing processing. The curing processing is the processing of curing the composition 13 in the contact state in which the flat surface 12a of the plane template 12 is in contact with the composition 13 on the substrate 11. For example, the controller CNT causes the substrate driver 132 to place the substrate 11 in the contact state below the curing device 112. As shown in FIG. 4, the controller CNT then causes the curing device 112 to emit the light 112a (ultraviolet light) to irradiate the composition 13 on the substrate 11, in which the flat surface 12a of the plane template 12 is in contact, with the light 112a (ultraviolet light). This makes it possible to cure the composition 13 between the plane template 12 and the substrate 11.

In step S15, the controller CNT causes the conveyance mechanism 130 to convey the substrate 11 in the contact state, for which the first processing device 110 has performed the curing processing, from the first processing device 110 to the second processing device 120. For example, the controller CNT causes the substrate driver 132 of the conveyance mechanism 130 to convey the stage 131 from the first processing device 110 to the second processing device 120. This makes it possible to convey the substrate 11 in the contact state, which is held by the stage 131, from the first processing device 110 to the second processing device 120. In this embodiment, the conveyance mechanism 130 conveys (places) the substrate 11 in the contact state at the processing position P1 of the second processing device 120.

In step S16, the controller CNT causes the ion generator 129 to start to ionize a gas in the second processing device 120. That is, the controller CNT causes the ion generator 129 to start to emit soft X-rays 129a and start to ionize a gas around the substrate 11 in the contact state, which is placed at the processing position P1. In this embodiment, the ion generator 129 is placed at a position on the opposite side of the processing position P1 to the unload inlet 140 (the unload position P2) and starts to ionize the gas after the conveyance mechanism 130 conveys the substrate 11 from the first processing device 110 to the second processing device 120.

In step S17, the controller CNT causes the second processing device 120 to perform separation processing. The separation processing is the processing of separating the plane template 12 from the composition 13 on the substrate 11 having undergone curing processing by the first processing device 110 and is sometimes called mold release processing. The separation processing is performed while the substrate 11 is placed at the processing position P1.

For example, as shown in FIG. 5A, the controller CNT causes the mold driver 123 to lower the mold holder 122 and make it approach the plane template 12 in contact with the composition 13 on the substrate 11. When the plane template 12 comes into contact with the mold holder 122, the controller CNT causes the mold holder 122 to hold the plane template 12 (holding operation). As shown in FIGS. 5B and 5C, the controller CNT then causes the mold driver 123 to raise the mold holder 122 and bring it far from the substrate 11, thereby separating the plane template 12 from the cured composition 13 on the substrate 11 (separating operation). At this time, the force generated by the mold driver 123 is called a separating force and controlled by the controller CNT.

When a separating operation is started, an ion supply device 118 has already been activated, and the surroundings of the substrate 11 and the plane template 12 are filled with an ionized gas. As the separation processing (separating operation) proceeds, the gap between the substrate 11 and the plane template 12 becomes a negative pressure, and the ionized gas is attracted into the gap by an air current 151 flowing forward through the gap, as shown in FIGS. 5B and 5C. This can enhance the neutralization effect (neutralization speed) with respect to the substrate 11 (the composition 13) and the plane template 12. At this time, as the speed of separating the substrate 11 from the plane template 12 increases, the ionized gas is attracted into the gap between the substrate 11 and the plane template 12 more efficiently, thus further enhancing the neutralization effect.

The second processing device 120 may be provided with a negative pressure suction devices 150 (negative pressure suction ports) on the opposite side of the substrate 11 and the plane template 12 (processing position) to the ion generator 129. The negative pressure suction devices 150 are placed so as to be able to suck a gas from the gap between the substrate 11 and the plane template 12. Providing the negative pressure suction devices 150 described above can further enhance the neutralization effect because the gas ionized by the ion generator 129 can be attracted into the gap more efficiently. Although the negative pressure suction devices 150 are provided for both the mold driver 123 and the stage 131, limitation is not made thereto, and the negative pressure suction device 150 may be provided for only one of the mold driver 123 and the stage 131 or provided for a component other than the second processing device 120. The negative pressure suction device 150 may be provided for the mold holder 122.

The timing at which the ion generator 129 starts to ionize the gas in step S16 is preferably after the substrate 11 in the contact state is conveyed from the first processing device 110 to the second processing device 120 by the conveyance mechanism 130 and before the separation processing in step S17 is started. More specifically, the timing at which the ion generator 129 starts to ionize a gas is preferably before the start of a holding operation in separation processing. In this case, in the separation processing, the gas around the substrate 11 in the contact state, which is placed at the processing position P1 of the second processing device 120, has been sufficiently ionized, and hence the neutralization effect can be enhanced.

In step S18, the controller CNT causes the conveyance mechanism 130 to move the substrate 11 to the unload position P2 (the unload inlet 140 in this embodiment) to unload the substrate 11 having undergone the separation processing from the second processing device 120. For example, as shown in FIG. 6A, in order to place the substrate 11 at the unload position P2, the controller CNT moves the substrate 11 from the processing position P1 to the unload position P2 by causing the substrate driver 132 of the conveyance mechanism 130 to drive the stage 131. At this time, the negative pressure generated below the plane template 12 as the stage 131 moves from below the plane template 12 generates an air current 152 flowing forward to below the plane template 12. The air current 152 attracts the ionized gas to below the plane template 12. This can enhance the neutralization effect with respect to the plane template 12. Continuing the ionization of the gas by the ion generator 129 until the substrate 11 is placed at the unload position P2 as shown in FIG. 6B can further enhance the neutralization effect.

The neutralization effect based on the movement of the substrate 11 with respect to the plane template 12 will be described hereinafter. As shown in FIG. 6A, assume that the distance between the plane template 12 and the stage 131 below the plane template 12 in the Z direction when the substrate 11 starts to move to the unload position P2 is defined as a first distance D1. In addition, as shown in FIG. 6B, the distance between the plane template 12 and the base 133 below the plane template 12 in the Z direction when the substrate 11 is placed at the unload position P2 is defined as a second distance D2. In the planarization apparatus 100 according to this embodiment, the second distance D2 is larger than the first distance D1, specifically, 10 times or more the first distance D1. That is, moving the substrate 11 to the unload position P2 will increase the distance between the plane template 12 and the member located below the plane template 12 from the first distance D1 to the second distance D2 10 times or more the first distance D1. This will increase the volume of a gas that can be ionized by the ion generator 129, thereby enhancing the neutralization effect. Increasing the second distance D2 can enhance the neutralization effect. However, as the second distance D2 becomes a predetermined value or more, the neutralization effect hardly changes. In order to neutralize the plane template 12 by efficiently ionizing a gas, the second distance D2 is preferably 20 mm or more. If, for example, the second distance D2 is 10 mm, the neutralization time with respect to the plane template 12 is 100 sec or more. In contrast to this, if the second distance D2 is 20 mm, the neutralization time with respect to the plane template 12 can be greatly shortened to less than 25 sec. Note that the neutralization time is an index indicating an neutralization effect and can be defined as the time required to neutralize an object charged to ±1,000 V to ±100 V.

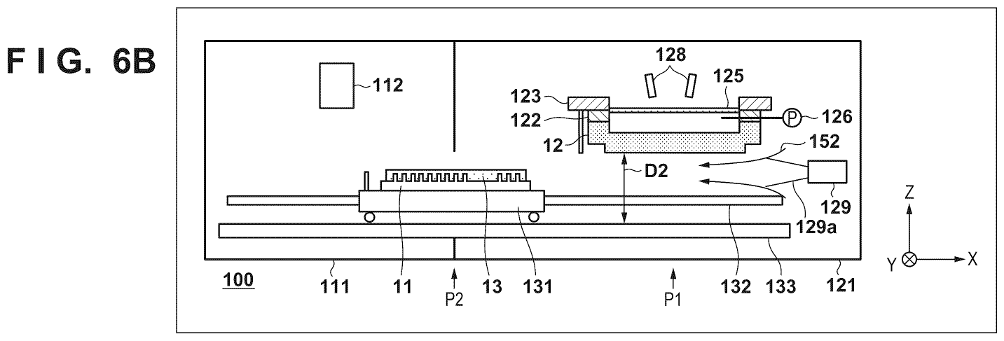

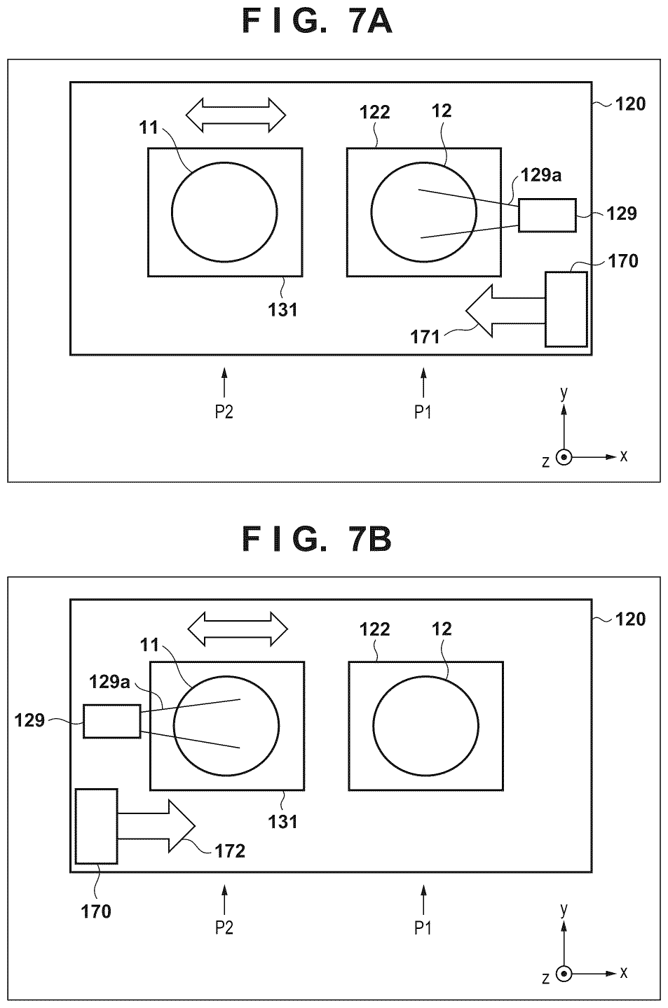

An arrangement example of the ion generator 129 will be described next. FIGS. 7A and 7B and FIGS. 8A and 8B are views for explaining an arrangement example of the ion generator 129. FIGS. 7A and 7B and FIGS. 8A and 8B are views of the second processing device 120 seen from above (+Z direction). FIGS. 7A and 7B and FIGS. 8A and 8B show the mold holder 122, the plane template 12 held by the mold holder 122, the stage 131, the substrate 11 held by the stage 131, and the ion generator 129. FIGS. 7A and 7B and FIGS. 8A and 8B also show the processing position P1 at which the substrate 11 is placed when separation processing is performed and the unload position P2 at which the substrate 11 is placed to unload the substrate 11 from the second processing device 120.

As shown in FIG. 7A, in the second processing device 120 according to this embodiment, the ion generator 129 is placed at a position on the opposite side of the processing position P1 to the unload position P2. That is, the ion generator 129 is placed on a side of the mold holder 122 in a direction (+X direction) opposite to a direction (−X direction) in which the stage 131 (the substrate 11) moves from below the plane template 12 held by the mold holder 122. With this placement, if, for example, the ion generator 129 includes a soft X-ray ionizer, a shielding object that blocks the soft X-rays 129a is removed from below the plane template 12 when the stage 131 moves away from below the plane template 12 in the −X direction. As a result, the space below the plane template 12 can be directly irradiated with the soft X-rays 129a, and hence the amount of gas ionized below the plane template 12 increases. This makes it possible to efficiently neutralize the plane template 12.

In addition, the second processing device 120 may be provided with an air current generator 170 that generates an air current 171 flowing forward in the same direction (−X direction) as the emitting direction of the soft X-rays 129a from the ion generator 129. The air current generator 170 is a mechanism that sends out a gas. As a gas to be sent out from the air current generator 170, clean air can be used. The clean air may include outer air but air passing through a filter is preferably used. When the air current 171 in the X direction is generated by the air current generator 170 in a state in which the ion generator 129 is activated (a state in which the soft X-rays 129a are mitted), ionized gas is sent to below the plane template 12 accompanying the air current 171. This can enhance the neutralization effect.

FIG. 7B shows an example in which the ion generator 129 is placed on the same side of the processing position P1 as the unload position P2. That is, as shown in FIG. 7B, the ion generator 129 is placed on a side of the mold holder 122 in the same direction (−X direction) as the direction in which the stage 131 (the substrate 11) moves from below the plane template 12 held by the mold holder 122. In this case, the air current generator 170 may be placed to generate an air current 172 flowing forward in the same direction (+X direction) as the emitting direction of the soft X-rays 129a from the ion generator 129.

FIG. 8A shows an example in which the two ion generators 129 are arranged so as to sandwich the processing position P1 in the X direction. In this case, each ion generator 129 may be placed to make the soft X-rays 129a propagate through the center of the gap between the plane template 12 and the substrate 11. In the example of FIG. 8A, enhancing the neutralization effect of one of the two ion generators 129 which is nearer the plane template 12 more than that of the other ion generator 129 can enhance the neutralization effect with respect to the plane template 12. In this case, in the example of FIG. 8A, the air current generator 170 is preferably placed to generate an air current flowing forward in the same direction as the emitting direction of the soft X-rays 129a from one of the two ion generators 129 which is nearer the plane template 12.

FIG. 8B shows an example provided with an ion generator 129′ placed at a position on the opposite side of the processing position P1 to the unload position P2 and configured to emit the soft X-rays 129a in the +Z direction in addition to the ion generator 129 that emits the soft X-rays 129a in the −X direction. The ion generator 129′ is placed on the stage 131. With this placement, when the stage 131 (the substrate 11) moves from below the plane template 12 held by the mold holder 122, the ion generator 129′ can ionize a gas around the plane template 12. In addition, the gas ionized by the ion generator 129′ can be drawn to below the plane template 12 accompanying the movement of the stage 131 from below the plane template 12. That is, the neutralization effect of the plane template 12 can be enhanced.

In this manner, the ion generator 129 is preferably placed in any of the forms shown in FIGS. 7A and 7B and FIGS. 8A and 8B. In this embodiment, the second processing device 120 may be provided with a plurality of ion generators 129 instead of one ion generator 129. In addition, in this embodiment, the second processing device 120 may be provided with the air current generator 170 that generates an ambient air current in the separation processing performed by the second processing device 120. The air current generator 170 is preferably placed to generate an air current flowing from the ion generator 129 to below the plane template 12. This makes it possible to efficiently send the gas ionized by the ion generator 129 to below the plane template 12 and efficiently neutralize the plane template 12.

In this case, if, for example, the ion generator 129 is a soft X-ray ionizer, the neutralization time tends to increase with a decrease in the gap (to be sometimes referred to as a gap distance hereinafter) between the plane template 12 and the substrate 11. It is known that the neutralization time increases in proportion to the square of the distance between the ion generator 129 (ionizer) and the plane template 12 as a neutralization target, that is, the distance (to be sometimes referred to as an irradiation distance hereinafter) that soft X-rays emitted from the ion generator 129 propagate. This is because as soft X-rays are ionized upon collision with atoms and molecules in a gas, the energy necessary for the ionization of the soft X-rays gradually decreases. The neutralization ability of the ion generator 129 (ionizer) depends on the tube current, and the neutralization speed of a neutralization target increases with an increase in tube current. Accordingly, the gap distance, the irradiation distance, and the tube current are preferably adjusted to set optimal neutralization conditions. For example, increasing the tube current will improve the neutralization ability, and hence the gap distance may be reduced, or the irradiation distance may be increased in favor of design. Likewise, increasing the gap distance makes it possible to efficiently neutralize the gas by ionizing it, and hence the tube current may be reduced, or the irradiation distance may be increased. Note that the tube voltage of the ion generator 129 (ionizer) is preferably 4.5 kV or more.

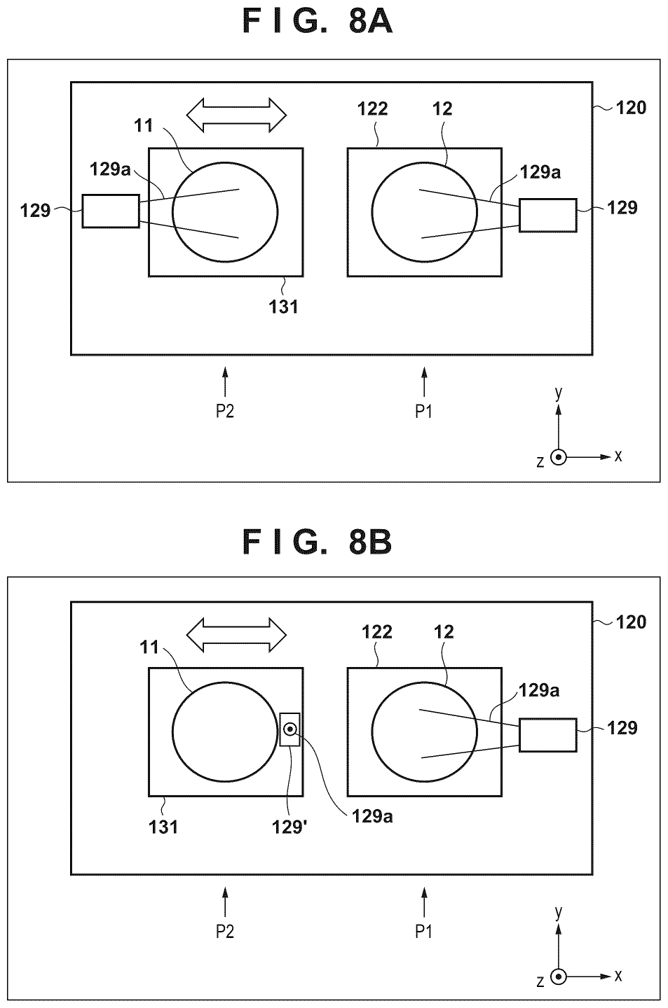

As shown in FIG. 9, the second processing device 120 according to this embodiment may include a potential measuring device 180 that measures the surface potential of the plane template 12 charged by peeling charge. Using the potential measuring device 180 makes it possible to measure the polarity and magnitude of peeling charge that has occurred on the plane template 12. For example, as shown in FIG. 9A, the potential measuring device 180 can be placed on the base 133 below the plane template 12 held by the mold holder 122. In this case, when the stage 131 has moved and disappeared from below the plane template 12, the potential measuring device 180 can measure the surface potential of the plane template 12. Alternatively, as shown in FIG. 9B, the potential measuring device 180 may be placed on the stage 131. In this case, when the stage 131 is moved and placed below the plane template 12, the potential measuring device 180 can measure the surface potential of the plane template 12 in this state. Providing the potential measuring device 180 on the second processing device 120 in this manner enables the controller CNT to determine the timing of stopping the ionization of a gas by the ion generator 129 based on the measurement result obtained by the potential measuring device 180. If, for example, the measured value of the potential of the plane template 12 by the potential measuring device 180 becomes less than a threshold (for example, less than 100 V), the controller CNT can stop ionizing the gas by the ion generator 129. In contrast to this, if the measured value of the potential of the plane template 12 by the potential measuring device 180 becomes equal to or more than a threshold (for example, becomes equal to or more than 100 V), the controller CNT can continue the ionization of the gas by the ion generator 129. Note that the potential measuring device 180 may be provided outside the second processing device 120.

As described above, the planarization apparatus 100 according to this embodiment can include the first processing device 110 that performs curing processing, the second processing device 120 that performs separation processing, and the conveyance mechanism 130 that conveys the substrate 11 having undergone the curing processing by the first processing device 110 to the second processing device 120. The second processing device 120 includes the ion generator 129 that ionizes a gas around the substrate 11 and the plane template 12 in separation processing. This makes it possible to neutralize the plane template 12 on which peeling charge has occurred in planarization processing (separation processing).

### Other Embodiments

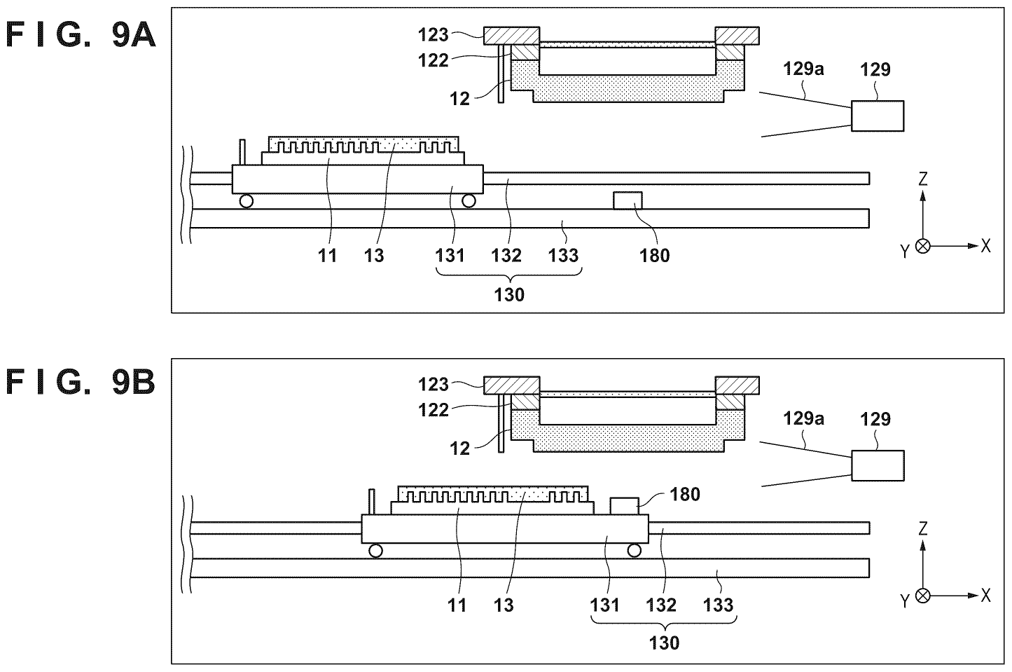

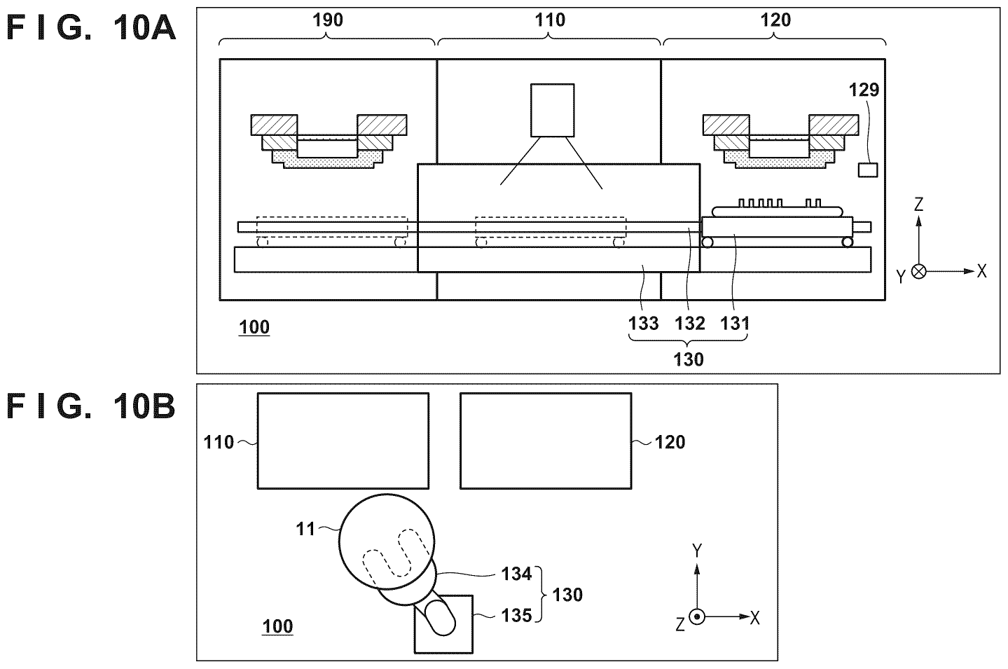

The above embodiment has exemplified the case where the second processing device 120 is configured to perform both contact processing and separation processing. However, limitation is not made thereto, and the second processing device 120 may be configured to perform only separation processing. In this case, as shown in FIG. 10A, a third processing device 190 that performs contact processing can be provided for a planarization apparatus 100 as a device separate from the second processing device 120. The third processing device 190 can have the same arrangement as that of the second processing device. In the planarization apparatus 100 including the third processing device in addition to a first processing device 110 and the second processing device 120, after the third processing device 190 performs contact processing, a conveyance mechanism 130 conveys a substrate 11 having undergone the contact processing to the first processing device 110. After the first processing device 110 performs curing processing, the conveyance mechanism 130 conveys the substrate 11 having undergone the curing processing to the second processing device 120. The second processing device 120 performs separation processing. In the planarization apparatus 100 including the third processing device 190, an ion generator 129 can be provided for only the second processing device 120.

The above embodiment has exemplified the case where the conveyance mechanism 130 is constituted by the stage 131 and the substrate driver 132. However, limitation is not made thereto, and the conveyance mechanism 130 may be configured to have a hand 134 that holds the substrate 11 and a driver 135 that drives the hand 134, as shown in FIG. 10B. In this case, the conveyance mechanism 130 can be provided outside the first processing device 110 and the second processing device 120.

### Embodiment of Article Manufacturing Method

An article manufacturing method according to the embodiment of the present invention is suitable for manufacturing an article, for example, a microdevice such as a semiconductor device or a device having a microstructure. The article manufacturing method according to this embodiment includes a planarization step of planarizing a composition on a substrate by using the above planarization apparatus, a processing step of processing the substrate having undergone the planarization step, and a manufacturing step of manufacturing an article from the substrate having undergone the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

A planarization step uses a mold (plane template) having a flat surface on which no concave-convex pattern is formed. In this step, planarization processing is performed to form a composition on the substrate so as to planarize the composition using the flat surface of the plane template. The planarization processing includes curing the curable composition supplied onto the substrate by irradiating the composition with light or heating the composition in a state in which the flat surface of the plane template is in contact with the composition. Such planarization processing (planarization step) can be applied to the above planarization apparatus that planarizes a composition on a substrate by using a plane template.

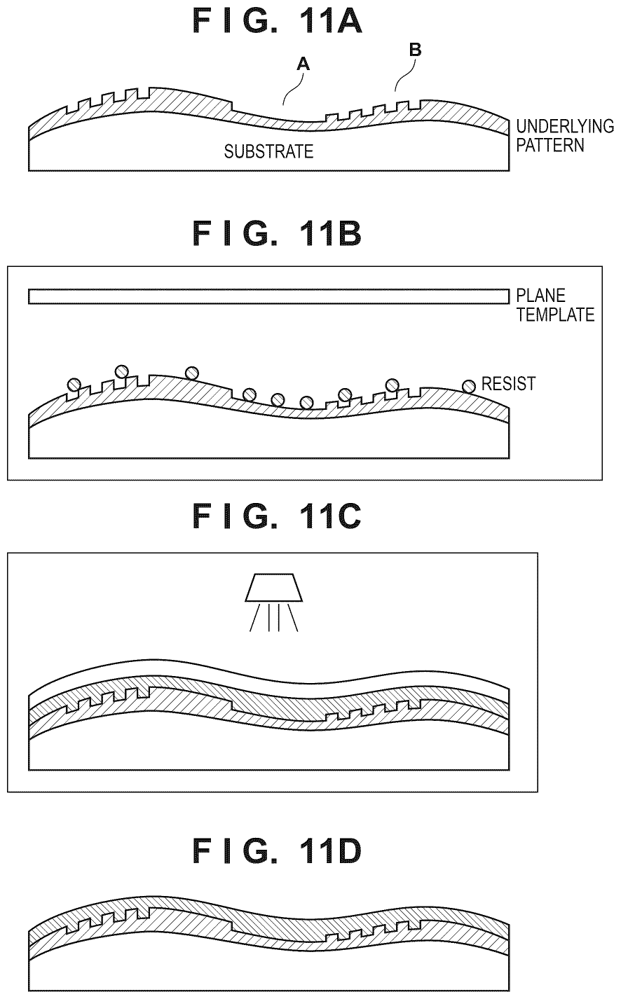

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 11A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Patent No. 9,415,418 proposes a technique of forming a continuous film by application of a resist serving as a planarization layer by an inkjet dispenser and pressing by a plane template. Also, U.S. Pat. No. 8,394,282 proposes a technique of reflecting a topography measurement result on a substrate side on density information for each position to instruct application by an inkjet dispenser. The above planarization apparatus can be applied for performing local planarization in a substrate surface by pressing a plane template as the mold against an uncured resist applied in advance.

FIG. 11A shows a substrate before planarization processing. In the isolated pattern region A, the area of a pattern convex portion is small. In the repetitive dense pattern region B, the ratio of the area of a pattern convex portion to the area of a pattern concave portion is 1:1. The average height of the isolated pattern region A and the repetitive dense pattern region B changes depending on the ratio of the pattern convex portion.

FIG. 11B shows a state in which the resist that forms the planarization layer is applied to the substrate. FIG. 11B shows a state in which the resist is applied by an inkjet dispenser based on the technique proposed in U.S. Pat. No. 9,415,418. However, a spin coater may be used to apply the resist. In other words, the above planarization apparatus can be applied if a step of pressing a plane template against an uncured resist applied in advance to planarize the resist is included.

As shown in FIG. 11C, the plane template is made of glass or quartz that passes ultraviolet light, and the resist is cured by irradiation of ultraviolet light from a light source. For the moderate unevenness of the entire substrate, the plane template conforms to the profile of the substrate surface. After the resist is cured, the plane template is separated from the resist, as shown in FIG. 11D.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-212322 filed on Dec. 15, 2023, which is hereby incorporated by reference herein in its entirety.

What is claimed is:

1. A planarization apparatus that planarizes a composition on a substrate by using a member having a flat surface, the apparatus comprising:
a first processing device configured to perform curing processing of curing the composition on the substrate in a contact state in which the flat surface of the member is in contact with the composition;
a second processing device configured to perform separation processing of separating the member from the composition on the substrate that has undergone the curing processing by the first processing device and is in the contact state; and
a conveyance mechanism configured to convey the substrate having undergone the curing processing by the first processing device to the second processing device,
wherein the second processing device includes an ion generator configured to ionize a gas around the substrate in the contact state.

2. The apparatus according to claim 1, wherein the ion generator starts to ionize the gas around the substrate in the contact state after the conveyance mechanism conveys the substrate from the first processing device to the second processing device.

3. The apparatus according to claim 2, wherein the ion generator starts to ionize the gas around the substrate in the contact state before the separation processing is started.

4. The apparatus according to claim 2, wherein the second processing device includes a holder configured to hold the member in contact with the composition on the substrate,
the separation processing includes a holding operation of causing the holder to hold the member by bringing the holder close to the member in contact with the composition on the substrate, and a separating operation of separating the member from the composition on the substrate by bringing the holder far from the substrate after the holding operation, and
the ion generator starts to ionize the gas around the substrate in the contact state before the holding operation is started.

5. The apparatus according to claim 1, wherein the second processing device performs the separation processing in a state in which the substrate is placed at a processing position and moves the substrate from the processing position to an unload position for unloading the substrate from the second processing device after the separation processing is completed, and
the ion generator is placed at a position on an opposite side of the processing position to the unload position.

6. The apparatus according to claim 5, wherein the ion generator continues ionization of a gas until the substrate is placed at the unload position.

7. The apparatus according to claim 1, wherein the ion generator includes an emitter configured to emit soft X-rays.

8. The apparatus according to claim 1, wherein the conveyance mechanism includes a stage configured to move over the first processing device and the second processing device while holding the substrate.

9. The apparatus according to claim 1, wherein the second processing device is configured to further perform contact processing of bringing the member into contact with the composition on the substrate before the first processing device performs the curing processing, and
the conveyance mechanism conveys the substrate having undergone the contact processing by the second processing device to the first processing device and conveys the substrate having undergone the curing processing by the first processing device to the second processing device.

10. The apparatus according to claim 1, further comprising a third processing device configured to perform contact processing of bringing the member into contact with the composition on the substrate,
wherein the conveyance mechanism conveys the substrate having undergone the contact processing by the third processing device to the first processing device and conveys the substrate having undergone the curing processing by the first processing device to the second processing device.

11. An article manufacturing method comprising:
planarizing a composition on a substrate by using a planarization apparatus defined in claim 1;
processing the substrate having undergone the planarizing; and
manufacturing an article from the substrate having undergone the processing.
